(19) United States
(12) Patent Application Publication
(10) Pub. No.: US 2025/0015053 A1
(43) Pub. Date: Jan. 9, 2025

(54) BARE FLIP-CHIP DIE STACK AND THE FABRICATION METHOD AND TOOLING THEREOF

(71) Applicant: Qorvo US, Inc., Greensboro, NC (US)

(72) Inventors: Tarak A. Railkar, Plano, TX (US); James Edwin Halvorson, Allen, TX (US); Jackline Lew, Plano, TX (US); Walid M. Meliane, Frisco, TX (US)

(21) Appl. No.: 18/655,986

(22) Filed: May 6, 2024

Related U.S. Application Data
(60) Provisional application No. 63/511,801, filed on Jul. 3, 2023.

(51) Int. Cl. H01L 25/065; H01L 21/683; H01L 23/00

(52) U.S. Cl. CPC H01L 25/0657; H01L 21/6835; H01L 24/13; H01L 24/16; H01L 24/81; H01L 2221/68318; H01L 2224/13147; H01L 2224/16145; H01L 2224/8121; H01L 2224/81815; H01L 2225/06513; H01L 2924/014

(57) ABSTRACT

One aspect of the present disclosure pertains to a method of assembling a flip-chip die stack. The method includes picking a bottom die where the bottom die incudes first interconnect bumps. The method includes placing the bottom die into an opening of a fabrication tool. The bottom die has an exposed portion hovering over an air cavity below the opening. The method includes picking a top die where the top die includes second interconnect bumps. The method includes placing the top die onto the bottom die to form a stacked die structure, inserting the fabrication tool containing the stacked die structure into a reflow oven, and reflowing the stacked die structure. After reflowing the stacked die structure, the second interconnect bumps are bonded to landing pads of the bottom die, and the first interconnect bumps remain unbonded.

### PRIORITY DATA

This application claims the benefit of U.S. Provisional Application No. 63/511,801 filed Jul. 3, 2023, the entirety of which is herein incorporated.

### FIELD OF THE DISCLOSURE

The present disclosure relates to a bare or substrate-less flip-chip die stack and a process for making the same, and more particularly to a fabrication tool that allows for fabricating the bare flip-chip die stack such that a bottom die of the die stack is supported primarily along the sides of the die and not attached to a substrate or other types of carrier base during assembly.

### BACKGROUND

The wide utilization of microelectronic devices drives the rapid development of radio frequency (RF) and power technologies in integrated circuits (ICs). To meet the demand of increasingly higher performance ICs, flip-chip techniques are used for higher signal density, faster signal propagation, and sometimes smaller die size. Stacked flip-chip techniques involve directly placing one flip-chip die onto another flip-chip die for tighter interconnectivity between components and faster communication between the components. For example, in a flip-chip process, interconnect bumps are formed on a front side of a first die, then the die is flipped, and the interconnect bumps are placed and bonded onto landing pads of a second die or board. Thereafter, additional dies may be flipped and bonded to the landing pads of the first die until achieving a desired stacked package.

However, current flip-chip techniques require the flip-chip die stack to be attached to a carrier base at the bottom. The carrier base may be a laminate carrier, a metal lead frame, a printed circuit board, a ceramic substrate, or other types of substrates. Such processes result in microelectronic components that can then be assembled into the customer's applications. However, there are times when the customer requires stacked flip-chip sub-assemblies without the underlying carrier base. This is to reduce the signal paths between the active elements on the die and other elements in the circuitry.

Accordingly, there is a need for assembling a substrate-less flip-chip die stack capable of easy and flexible integration into a next-level-assembly. It is therefore an object of the present disclosure to provide a method and a fabrication tool for fabricating and enabling a substrate-less and bare flip-chip die stack.

### SUMMARY

The present disclosure relates to a bare or substrate-less flip-chip die stack and a process for making the same, and more particularly to a fabrication tool that allows for fabricating the bare flip-chip die stack such that a bottom die of the die stack is suspended and not attached to a substrate or other type of carrier base.

In one aspect, the present disclosure provides a method of assembling a flip-chip die stack. The method includes picking a bottom die where the bottom die includes first interconnect bumps. The method includes placing the bottom die into an opening of a fabrication tool for a die. The bottom die has an exposed portion hovering over an air cavity below the opening. The method includes picking a top die where the top die includes second interconnect bumps. The method includes placing the top die onto the bottom die to form a stacked die structure, inserting the fabrication tool containing the stacked die structure into a reflow oven, and reflowing the stacked die structure. After reflowing the stacked die structure, the second interconnect bumps are bonded to landing pads of the bottom die, and the first interconnect bumps remain unbonded.

In another aspect, the present disclosure provides a fabrication tool for assembling a flip-chip stack. The fabrication tool includes a core body, an opening in the core body for receiving a flip-chip die having interconnect bumps, and an air cavity below the opening. The opening has a first width, the air cavity has a second width, and the first width is greater than the second width. And when the flip-chip die is present, the interconnect bumps are suspended in the air cavity.

In another aspect, the present disclosure provides a fabrication tool for assembling a flip-chip stack. The fabrication tool includes a core body, one or multiple openings in the core body for receiving multiple flip-chip dies, and air cavities below each of the openings. Each sidewall of the openings extends beyond each sidewall of the air cavities along a horizontal direction. And when the flip-chip dies are present, a bottom surface of each of the flip-chip dies are exposed in the air cavities.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description, serve to explain the principles of the disclosure.

FIG. 1A illustrates a fabrication tool for assembling a flip-chip die stack, according to an embodiment of the present disclosure.

FIG. 1B illustrates a cross-sectional view of the fabrication tool of FIG. 1A, cut along the line B-B′, according to an embodiment of the present disclosure.

FIG. 2A illustrates a fabrication tool for assembling a flip-chip die stack, according to another embodiment of the present disclosure.

FIG. 2B illustrates a cross-sectional view of the fabrication tool of FIG. 2A, cut along the line B-B′, according to an embodiment of the present disclosure.

FIG. 3A illustrates a fabrication tool for assembling a flip-chip die stack, according to another embodiment of the present disclosure.

FIG. 3B illustrates a cross-sectional view of the fabrication tool of FIG. 3A, cut along the line B-B′, according to an embodiment of the present disclosure.

FIG. 4 illustrates a flow chart of a method to form a flip-chip die stack, according to an embodiment of the present disclosure.

FIGS. 5-8 illustrate the formation of a flip-chip die stack at intermediate stages of fabrication and processed in accordance with the method of FIG. 4, according to an embodiment of the present disclosure.

FIGS. 9A-9B and 10A-10B illustrate die openings having other shapes for additional embodiments of a fabrication tool.

It will be understood that for clear illustrations, the drawings may not be drawn to scale.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

When a number or a range of numbers is described with “about,” “approximate,” and the like, the term is intended to encompass numbers that are within a reasonable range including the number described, such as within +/−10% of the number described, or other values as understood by person skilled in the art. For example, the term “about 5 mm” may encompass the dimension range from 4.5 mm to 5.5 mm. And when comparing a dimension or size of a feature to another feature, the phrases “substantially the same,” “essentially the same,” “of similar size,” and the like, are understood to be within +/−10% between the compared features. Further, disclosed dimensions of the different features can implicitly disclose dimension ratios between the different features.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

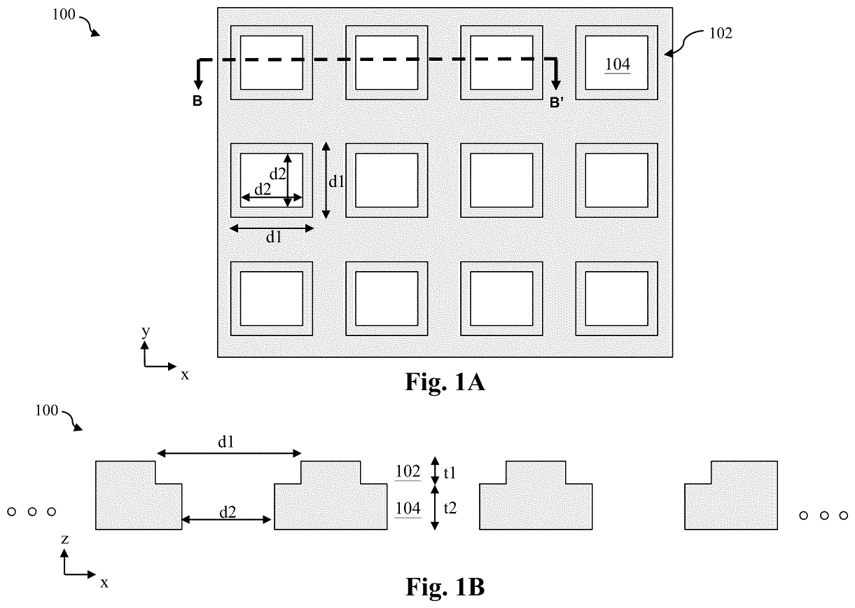

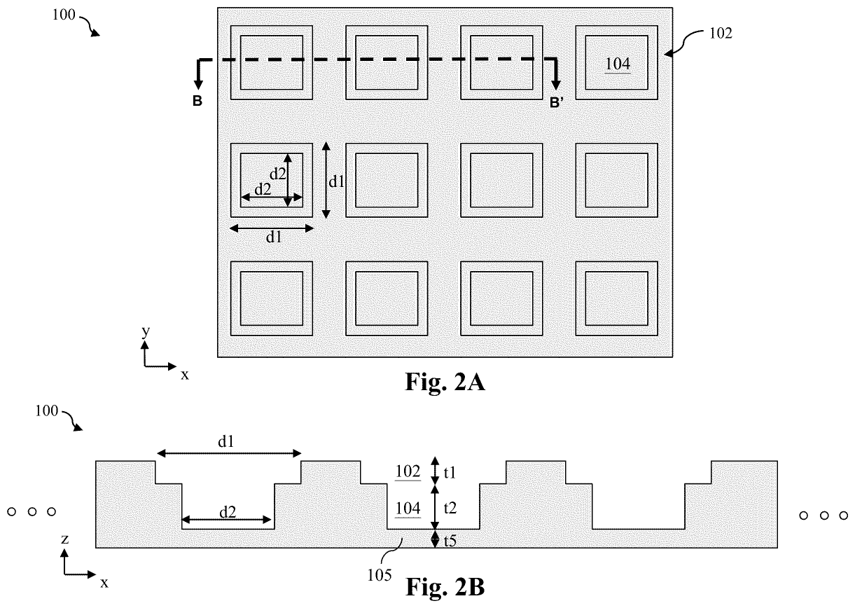

FIG. 1A illustrates a fabrication tool 100 for assembling a flip-chip die stack. In the present embodiment, the fabrication tool 100 can be formed from any suitable material composition, for example aluminum, stainless steel, graphite, titanium, or a combination thereof. For example, the fabrication tool 100 can be made of titanium due to titanium's high corrosion resistance and high strength-to-weight ratio. For another example, the fabrication tool 100 can be made of aluminum due to aluminum's low cost and case of fabrication. Both materials can be used to produce a fabrication tool 100 that function as described through the processing steps described here. The fabrication tool 100 may include one or more openings, which is herein referred to as die openings 102, for receiving flip-chip dies. FIG. 1A shows the fabrication tool 100 having an array of twelve die openings 102 spaced in three rows and four columns. However, the present disclosure is not limited thereto. For example, the fabrication tool may have more or less die openings 102 depending on the received die profiles. A spacing between adjacent die openings 102 may be adjusted according to design considerations. Such spacing may be smaller if the material composition of the fabrication tool 100 has low thermal conductivity (e.g., made of titanium or stainless steel). In an embodiment, the spacing between adjacent die openings 102 is at least 1 mm.

FIG. 1B illustrates a cross-sectional view of the fabrication tool 100 cut along the line B-B′ in FIG. 1A. Now referring to both FIG. 1A and FIG. 1B, each of the die openings 102 includes an air cavity 104 below the die opening 102. The air cavities 104 extend within the die openings 102 and are aligned to a center point of the die openings 102 along the x and y direction. In other words, a perimeter of the die openings 102 surrounds the air cavities 104 and forms a shelf feature or landing area for receiving flip-chip dies. Note that the shapes of the die openings 102 and the air cavities 104 may be modified depending on the shape of received flip-chip dies. In the embodiment shown, the die openings 102 may have a square shape having widths d1 in the x and y directions. In other embodiments, the die openings 102 may have a rectangular shape having different widths in the x and y directions. Similarly, in the embodiment shown, the air cavities 104 may have a square shape having widths d2 in the x and y directions. In other embodiments, the air cavities 104 may have a rectangular shape having different widths in the x and y directions that corresponds to rectangular shaped die openings 102. In even further embodiments, the die openings 102 and corresponding air cavities 104 may have rounded corners or have a circular shape.

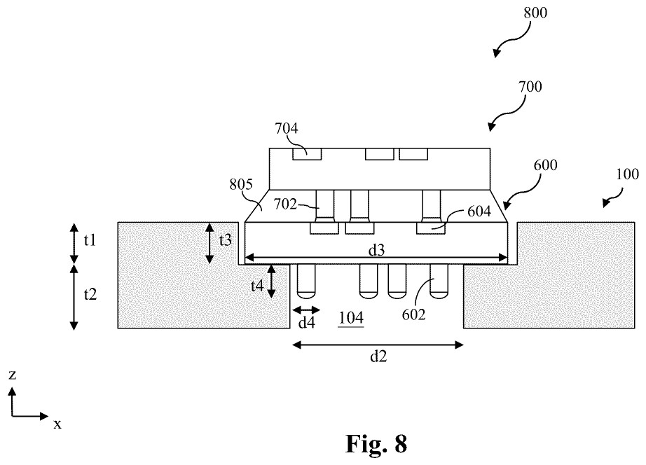

The width d1 corresponds to a width of a flip-chip die in the x or y direction. The width d1 should be big enough to fit the flip-chip die into the die openings 102. The dimensions of d1 will be explained in more detail with respect to FIG. 5. The width d2 corresponds to a width of a bottom portion of the flip-chip die in the x or y direction. The width d2 should be big enough to fit all the interconnect bumps that span across the bottom portion of the inserted flip-chip die. The dimensions of d2 will be explained in more detail with respect to FIG. 5. Referring now to FIG. 1B, each of the die openings 102 has a thickness (or depth) t1, and each of the air cavities 104 have a thickness (or depth) t2. In some embodiments, the thickness t2 is bigger than the thickness t1, as will be explained in more detail with respect to FIG. 5.

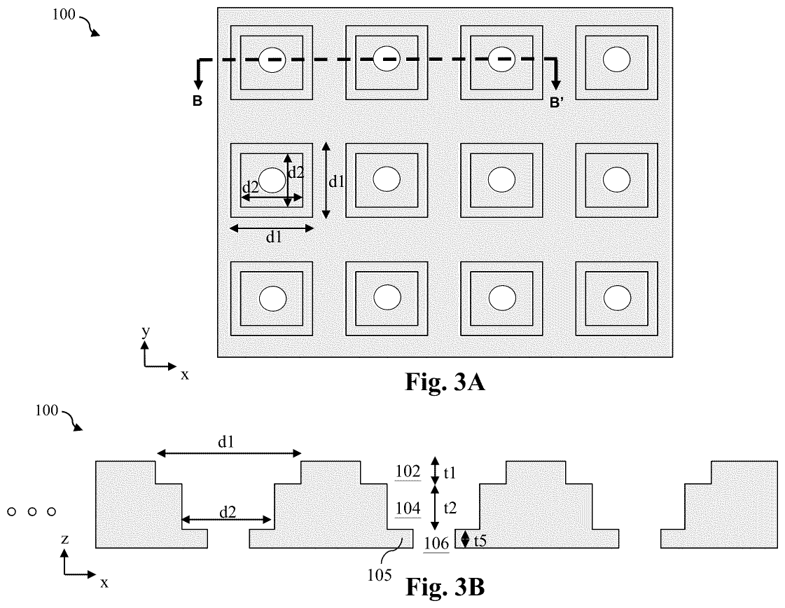

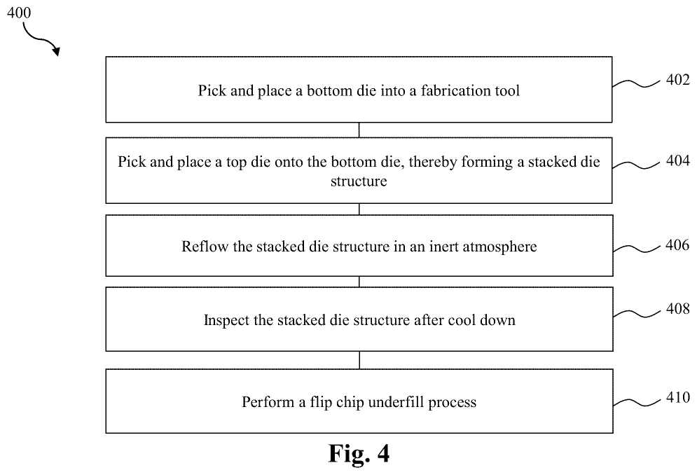

FIGS. 2A and 2B illustrate another embodiment of a fabrication tool 100.

FIGS. 2A and 2B are like FIGS. 1A and 1B, and the similar features will not be described again for the sake of brevity. The difference in FIGS. 2A and 2B is that the fabrication tool 100 includes a base portion 105 under the air cavities 104. As shown in FIGS. 2A and 2B, the base portion 105 may have a thickness t5. In some embodiments, the thickness t5 may be in a range between about 100 μm to about 500 μm. In an embodiment, the thickness t5 does not exceed 1 mm. Note that in FIGS. 1A and 1B, there is no such base portion under the air cavities 104, and the air cavities 104 penetrates completely through the fabrication tool 100.

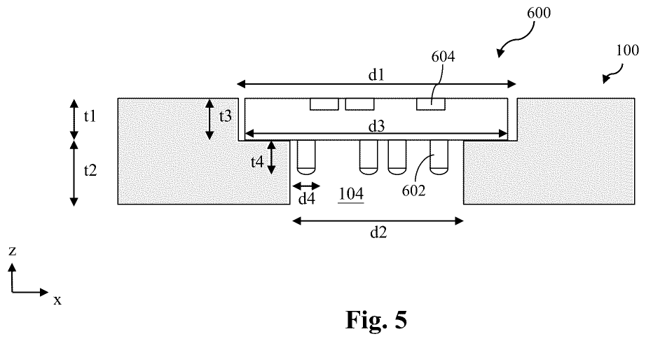

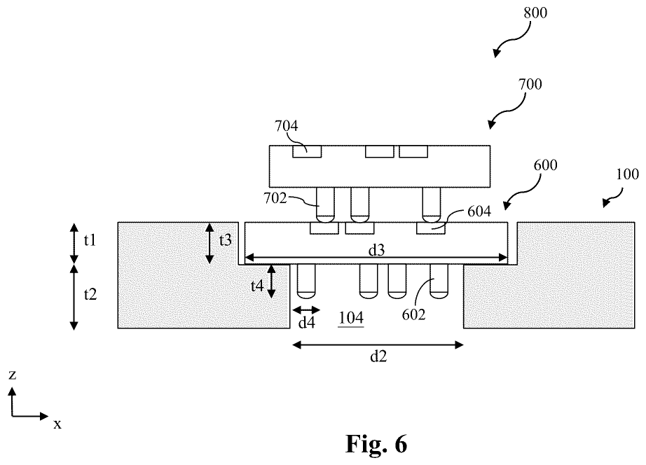

FIGS. 3A and 3B illustrate another embodiment of a fabrication tool 100. FIGS. 3A and 3B are like FIGS. 2A and 2B, and the similar features will not be described again for the sake of brevity. The difference in FIGS. 3A and 3B is that the fabrication tool 100 includes a through-hole cavity 106 that penetrates through the base portion 105. FIGS. 3A and 3B shows one or more through-hole cavity 106 below each of the air cavities 104, but the present embodiment is not limited thereto. For example, there may be two or more through-hole cavities 106 below each air cavities 104. Note that the embodiments shown in FIGS. 1A-1B and FIGS. 3A-3B each have air holes (i.e., air cavities 104 and/or through-hole cavities 106) that completely penetrates through the fabrication tool 100. During a reflow process, these air holes may provide air escape routes for expanded gas to escape. This will be explained in more detail with respect to FIG. 7.

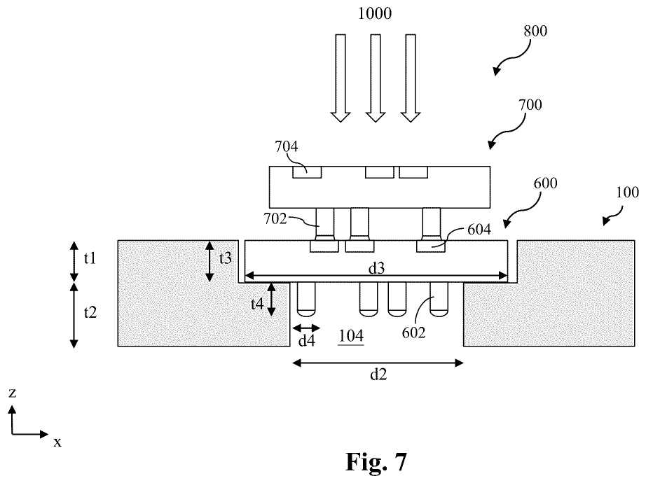

FIG. 4 illustrates a flow chart of a method 400 to form a flip-chip die stack, according to an embodiment of the present disclosure. FIGS. 5-8 illustrate the formation of a flip-chip die stack at intermediate stages of fabrication and processed in accordance with the method 400. FIGS. 5-8 illustrate a fabrication process using the fabrication tool 100 in FIGS. 1A-1B, but the same fabrication process may also be performed using the fabrication tool 100 in FIGS. 2A-2B and 3A-3B. Further, the fabrication process is described with respect to a single die opening 102, but such fabrication process can equally apply to other die openings 102 of the fabrication tool 100. Additional operations can be provided before, during, and after the method 400, and some of the operations described can be moved, replaced, or eliminated for additional embodiments of method 400.

Referring now to FIG. 5, the method 400 at operation 402 picks and places a bottom die 600 into a die opening 102 of a fabrication tool 100. The bottom die 600 may be a flip-chip die having various active and passive components, including but not limited to transistors, capacitors, resistors, metal routings, vias, and other circuit structures. The bottom die 600 includes interconnect bumps 602 and landing pads 604 on opposite sides of the die 600. For example, the interconnect bumps 602 are on the non-active side of the die 600, and the landing pads 604 are on the active side of the die 600. Alternatively, the interconnect bumps 602 are on the active side of the die 600 and the landing pads 604 are on the non-active side of the die 600. In either case, the bottom die 600 is picked and placed such that the interconnect bumps 602 face downwards in the z direction towards the air cavity 104. For case of description, the side where the interconnect bumps 602 are located is the bottom side, and the side where the landing pads 604 are located is the top side.

As previously described, the width d1 of the die opening 102 should be big enough in the x and/or y direction to receive a flip-chip die, such as the bottom die 600. The bottom die 600 has a width d3 in the x or y direction. In the present embodiment, the width d3 may range between about 2 mm to about 40 mm depending on die size. As such, the width d3 should be at least equal to or slightly bigger than the width d1. Similarly, the thickness t1 of the die opening 102 correspond to a thickness t3 of the bottom die 600 (when excluding the interconnect bumps 602). The thickness t3 may be in a range between about 25 μm to about 300 μm. The thickness t1 may be about equal to the thickness t3, although t1 may be bigger or smaller than t3 without departing from the scope of the present invention.

Still referring to FIG. 5, multiple interconnect bumps 602 are on the backside of the bottom die 600, and these bumps span across a bottom portion of the bottom die 600 in the x or y direction. The interconnect bumps 602 extrudes from the backside of the bottom die 600 and they are designed to land and bond to other circuit components in a next-level-assembly. The interconnect bumps 602 may be solder bumps or copper pillar (CuP) bumps. The solder bumps may include tin, lead, copper, and/or silver, and the CuP bumps may include a copper pillar having a solder cap at the end (like as shown). The solder cap may be made of tin, lead, copper, and/or silver. Each of the interconnect bumps 602 has a thickness (or height) t4 and a width d4. The thickness t4 may be in a range between about 10 μm to about 250 μm, and the width d4 may be in a range between about 10 μm to about 150 μm. Each of the interconnect bumps 602 are to suspend in air and not contact other components during a subsequent reflow process. Therefore, the thickness t2 of the air cavity 104 (previously described) should be greater than the thickness t4 of the interconnect bumps 602. In the present embodiment, the thickness t2 may be in a range between about 50 μm to about 500 μm. Due to this limitation, in some embodiments, the thickness t2 of the air cavity 104 may be greater than the thickness t1 of the die opening 102.

Still referring to FIG. 5, the width d2 of the air cavity 104 should be big enough to encompass all the interconnect bumps 602 that span across the bottom portion of the bottom die 600. The width d2 should also be small enough as to form the abovementioned shelf feature or landing area for receiving the bottom die 600. If d2 is too small, there is risk that the rightmost or leftmost interconnect bump 602 will land on the shelf feature or landing area, which is undesirable. If d2 is too big, d2 approaches too close to the width d1 and there would not be enough landing area for the bottom die 600. As such, d1 should be greater than d2 such that edges of the bottom die 600 securely lands on the landing area at the perimeter of the die opening 102, while allowing all the interconnect bumps 602 to suspend in the air cavity 104. To achieve this, a same amount of landing area extends from and beyond each of a sidewall of the air cavity 104 to each of a sidewall of the die opening 102 in the x and y direction. The difference in width between d1 and d2 may range between about 50 μm to about 2 mm depending on die size. As such, the landing area (or shelf feature) on all sides of the die opening (i.e., perimeter of the die opening 102) may range between about 25 μm to about 1 mm. In an embodiment, the landing area (or shelf feature) on each side is about 75 μm. In an embodiment, d1 is between about 2 mm to about 40 mm, and d2 is between about 1.95 mm to about 38 mm.

Referring now to FIG. 6, the method 400 at operation 404 picks and places a top die 700 onto the bottom die 600, thereby forming a stacked die structure 800. Like the bottom die 600, the top die 700 may be a flip-chip die having various active and passive components, including but not limited to transistors, capacitors, resistors, metal routings, vias, and other circuit structures. The top die 700 includes interconnect bumps 702 and landing pads 704 on opposite sides of the die 700. For example, the interconnect bumps 702 are on the non-active side of the die 700, and the landing pads 704 are on the active side of the die 700. Alternatively, the interconnect bumps 702 are on the active side of the die 700 and the landing pads 704 are on the non-active side of the die 700. In either case, the top die 700 is picked and placed such that the interconnect bumps 702 face downwards in the z direction towards the bottom dic 600. For case of description, the side where the interconnect bumps 702 are located is the bottom side, and the side where the landing pads 704 are located is the top side.

Still referring to FIG. 6, the top die 700 is placed onto the bottom die 600 such that the interconnect bumps 702 of the top die 700 lands on the landing pads 604 of the bottom die 600. The top die 700 may have same or different dimensions (width, thickness, etc.) as the bottom die 600. However, in the present embodiment, sidewall edges of the top die 700 do not extend beyond sidewall edges of the bottom die 600 along the x or y direction. That is, the top die 700 is directly over a top surface of the bottom die 600 but not directly over a top surface of the fabrication tool 100. In some embodiments, before placing the top die 700 onto the bottom die 600, the interconnect bumps 702 are dipped in flux, and the flux treats an interface between the interconnect bumps 702 and the landing pads 604 of the bottom die 600. Note that the interconnect bumps 702 may be similar to the interconnect bumps 602 in terms of materials and dimensions.

Referring now to FIG. 7, the method 400 at operation 406 performs a reflow process 1000 to reflow the stacked die structure 800. In an embodiment, the reflow process includes reflowing the solder on the interconnect bumps 702 onto the landing pads 604 of the bottom die 600. In the present embodiment, the reflow process 1000 is performed in an inert atmosphere (i.e., oxygen-deprived or low-oxygen environment) to reduce risks of oxidation and ensure proper bonding. The reflow process 1000 includes inserting the fabrication tool 100 containing the stacked die structure 800 into a reflow oven and reflowing the stacked die structure 800. For example, the fabrication tool 100 is placed into a reflow oven, and the reflow oven is turned on to heat the stacked die structure 800. A reflow temperature for reflowing the stacked die structure 800 may be in a range between about 180 degrees Celsius to about 250 degrees Celsius. Note that the fabrication tool 100 should be designed such that it is capable to withstand the solder reflow temperature and related environment. After reflowing the stacked die structure 800, the interconnect bumps 702 are bonded to the landing pads 604 of the bottom die 600 while the interconnect bumps 602 remain suspended and unbonded. As described previously, the fabrication tool 100 is designed such that the interconnect bumps 602 hover and suspend in air and do not touch any other components. This prepares the stacked die structure 800 for a future next-level-assembly. Therefore, at this stage, the interconnect bumps 602 do not bond to anything because they are suspended in the air cavity 104 throughout the reflow process 1000. In an embodiment, after reflowing the stacked die structure 800, solder caps of the interconnect bumps 702 have a flattened bottom surface (due to reflow and bonding to landing pads 604), and solder caps of the interconnect bumps 602 have a rounded bottom surface (due to reflow and surface tension keeping it together as a droplet shape). The rounded bottom surface of the interconnect bumps 602 is desirable for future bonding to other circuit components.

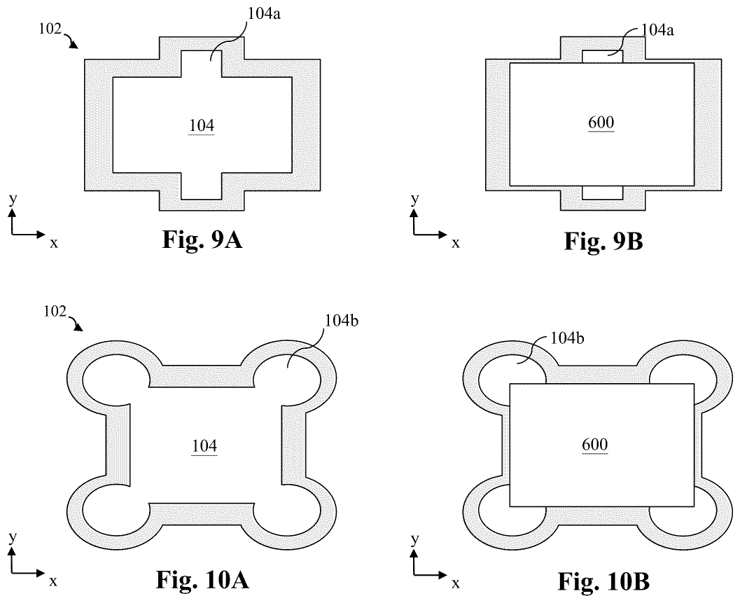

Still referring to FIG. 7, the reflow process 1000 may generate heated air that leads to gases expanding. If there are no routes for the heated air to escape, the reflow process 1000 risks moving or blowing away the stacked die structure 800. As such, the present disclosure contemplates fabrication tools 100 that provide air escape routes in various embodiments. For example, the fabrication tool 100 in the embodiments FIG. 1A-1B (and shown here in FIG. 7) has a through-hole air cavity 104 that penetrates completely through the fabrication tool 100. As such, the air cavity 104 provides air routes for heated air to escape. For another example, the fabrication tool 100 in the embodiments 3A-3B has one or more through-hole cavities 106 below each air cavities 104. As such, the through-hole cavities 106 provides air routes for heated air to escape. For both the embodiments in FIGS. 1A-1B and 3A-3B, escape air routes are provided in a bottom opening of the fabrication tool 100. However, the fabrication tool 100 in the embodiments 2A-2B does not have any air holes that completely penetrates through the fabrication tool 100. In some embodiments, this is still acceptable if the stacked dic structure 800 does not move too much. However, in other embodiments, escape air routes can still be provided through the top openings of the fabrication tool 100, as will be explained in more detail with respect to FIGS. 9A-9B and 10A-10B.

After reflowing, the method 400 at operation 408 inspects the stacked die structure 800 after cool down. This operation may include performing visual inspection or other quality control protocols to ensure the top die 700 and bottom die 600 are properly bonded together. Additional process steps may be performed to discard or to fix any malformed stacked die structures 800. Referring now to FIG. 8, the method 400 at operation 410 performs a flip chip underfill process to fill an underfill material 805 between the top die 700 and the bottom die 600. The underfill material 805 also surrounds the interconnect bumps 702. The underfill material 805 is not deposited on the fabrication tool 100. The underfill material 805 prevents mechanical fatigue by providing stress redistribution. The underfill material 805 may be a liquid encapsulant such as epoxy resins infused with silica particles. Note that the underfill process in operation 410 could also be performed later as part of a next-level-assembly process. In other embodiments, the underfill process in operation 410 may be omitted.

Additional operations can be provided before, during, and after the method 400, and some of the operations described can be moved, replaced, or eliminated for additional embodiments of method 400. For example, the method 400 may be repeated for all sites (i.e., die openings 102) of the fabrication tool 100. For another example, the method 400 may include other operation steps for providing flux at the bonding sites between the interconnect bumps 702 and the landing pads 604. For another example, the method 400 may include additional testing operations to make sure the reflowed stacked die structure 800 is operating according to design considerations. In any case, as described herein, the method 400 provides a method for fabricating a substrate-less, bare flip-chip die stack by using a fabrication tool 100 of the present disclosure.

FIGS. 9A-9B and 10A-10B illustrate die openings 102 having other shapes for additional embodiments of a fabrication tool 100. That is, the fabrication tool 100 described in FIGS. 1A-1B, 2A-2B, and 3A-3B may each incorporate the die openings 102 in FIGS. 9A-9B and 10A-10B. The die openings 102 in FIGS. 9A-9B and 10A-10B are designed to allow for air escape routes during the reflow process 1000 as described in operation 406. These air escape routes are provided through the top openings of the fabrication tool 100, and they provide pathways for trapped air when there is no air escape routes through bottom openings of the fabrication tool 100 (e.g., embodiment in FIGS. 2A-2B). Further, to provide additional air flow paths, these top opening escape routes may also be present in fabrication tools 100 already having air escape routes through bottom openings of the fabrication tools 100 (e.g., FIGS. 1A-1B and 3A-3B).

FIGS. 9A-9B shows die openings 102 enclosing air cavities 104 having protruding portions 104a extending along the y direction. In other embodiments, these protruding portions 104a may extend along the x direction or in both the x and y directions. Referring to FIG. 9B, when a bottom die 600 is placed over a landing area (shelf feature) of the die opening 102 and over an air cavity 104, the protruding portions 104a of the air cavity 104 extend beyond the outer sidewalls of a bottom die 600 in the y direction (or x direction). In this way, the bottom die 600 does not completely cover the air cavity 104. As such, portions of the protruding portions 104a provide exposed airways for trapped air to escape during a reflow process 1000.

FIGS. 10A-10B shows die openings 102 enclosing air cavities 104 having protruding portions 104b extending from corner portions of the air cavities 104. The present embodiment shows protruding portions 104b in all four corner portions, but there may be fewer protruding portions 104b in other embodiments. Referring to FIG. 9B, when a bottom die 600 is placed over a landing area (shelf feature) of the die opening 102 and over an air cavity 104, the protruding portions 104b of the air cavity 104 extend beyond the corner portions of a bottom die 600 in the x and y directions. In this way, the bottom die 600 does not completely cover the air cavity 104. As such, portions of the protruding portions 104a provide exposed airways for trapped air to escape during a reflow process 1000.

Those skilled in the art will recognize improvements and modifications to the preferred embodiments of the present disclosure. All such improvements and modifications are considered within the scope of the concepts disclosed herein and the claims that follow.

What is claimed is:

1. A method of assembling a flip-chip die stack, comprising:
picking a bottom die, the bottom die includes first interconnect bumps;
placing the bottom die into an opening of a fabrication tool, wherein the bottom die has an exposed portion hovering over an air cavity below the opening;
picking a top die, the top die includes second interconnect bumps;
placing the top die onto the bottom die to form a stacked die structure;
inserting the fabrication tool containing the stacked die structure into a reflow oven; and
reflowing the stacked die structure,
wherein after reflowing the stacked die structure, the second interconnect bumps are bonded to landing pads of the bottom die, and the first interconnect bumps remain unbonded.

2. The method of claim 1, wherein the air cavity has a greater depth than a height of the first interconnect bumps.

3. The method of claim 1, wherein the first and second interconnect bumps are copper pillar bumps.

4. The method of claim 1, wherein after reflowing the stacked die structure, solder caps of the second interconnect bumps have a flattened bottom surface, and solder caps of the first interconnect bumps have a rounded bottom surface.

5. The method of claim 1, wherein reflowing the stacked die structure includes heating the stacked die structure at a reflow temperature between about 180° C. to about 250° C.

6. The method of claim 1, wherein the fabrication tool has a material composition that includes aluminum, stainless steel, graphite, titanium, or a combination thereof.

7. The method of claim 1, further comprising:
inspecting the stacked die structure after the reflowing; and
performing a flip chip underfill process to fill an underfill material between the top die and the bottom die and surrounding the second interconnect bumps.

8. The method of claim 1, further comprising:
dipping the second interconnect bumps in flux before placing the top die onto the bottom die.

9. A fabrication tool for assembling a flip-chip stack, comprising:
a core body;
an opening in the core body for receiving a flip-chip die having interconnect bumps; and
an air cavity below the opening,
wherein the opening has a first width, the air cavity has a second width, and the first width is greater than the second width,
wherein when the flip-chip die is present, the interconnect bumps are suspended in the air cavity.

10. The fabrication tool of claim 9, wherein the first width is between about 2 mm to about 40 mm, and the second width is between about 1.95 mm to about 38 mm.

11. The fabrication tool of claim 9, wherein the opening forms a shelf feature having landing areas in the core body, and edges of the flip-chip die lands on the shelf feature when the flip-chip die is present.

12. The fabrication tool of claim 11, wherein the landing areas each have a width between about 25 μm to 1 about mm.

13. The fabrication tool of claim 9, wherein the air cavity fully penetrates through the core body.

14. The fabrication tool of claim 9, wherein the air cavity partially penetrates the core body, and the core body has a base portion below the air cavity, wherein the base portion has a thickness between about 100 μm to about 500 μm.

15. The fabrication tool of claim 14, further comprising a through-hole cavity below the air cavity, wherein the through-hole cavity fully penetrates through the base portion.

16. The fabrication tool of claim 9, wherein the opening has a first depth between 25 μm to 300 μm, and the air cavity has a second depth between about 50 μm to about 500 μm.

17. A fabrication tool for assembling a flip-chip stack, comprising:
a core body;
multiple openings in the core body for receiving multiple flip-chip dies; and
air cavities below each of the openings,
wherein each sidewall of the openings extends beyond each sidewall of the air cavities along a horizontal direction,
wherein when the flip-chip dies are present, a bottom surface of each of the flip-chip dies are exposed in the air cavities.

18. The fabrication tool of claim 17, wherein the core body is made of aluminum or stainless steel.

19. The fabrication tool of claim 17, wherein when the flip-chip dies are present, they do not completely cover the air cavities.

20. The fabrication tool of claim 17, wherein the air cavities have protruding portions that protrude from the sidewalls of the air cavities in a direction perpendicular to the horizontal direction.
